(19) United States
(12) Patent Application Publication
(10) Pub. No.: US 2024/0178292 A1
(43) Pub. Date: May 30, 2024

(54) SEPARATE EPITAXY IN MONOLITHIC STACKED AND STEPPED NANOSHEETS

(71) Applicant: INTERNATIONAL BUSINESS MACHINES CORPORATION, Armonk, NY (US)

(72) Inventors: Indira Seshadri, Niskayuna, NY (US); Su Chen Fan, Cohoes, NY (US); Jay William Strane, Warwick, NY (US); Stuart Sieg, Albany, NY (US); Shogo Mochizuki, Mechanicville, NY (US)

(21) Appl. No.: 17/994,487

(22) Filed: Nov. 28, 2022

(51) Int. Cl. H01L 29/423; H01L 27/088; H01L 29/06; H01L 29/417; H01L 29/66; H01L 29/775

(52) U.S. Cl. CPC H01L 29/42392; H01L 27/088; H01L 29/0673; H01L 29/41775; H01L 29/66553; H01L 29/775

(57) ABSTRACT

A semiconductor structure is presented including semiconductor layers of a first nanosheet stack, semiconductor layers of a second nanosheet stack formed over and having a stepped nanosheet formation with respect to the semiconductor layers of the first nanosheet stack, a first epitaxial growth formed adjacent the semiconductor layers of the first nanosheet stack, and a second epitaxial growth formed adjacent the semiconductor layers of the second nanosheet stack such that the second epitaxial growth has a stepped formation with respect to the first epitaxial growth. The second epitaxial growth has a volume greater than a volume of the first epitaxial growth.

### BACKGROUND

The present invention relates generally to semiconductor devices, and more specifically, to constructing a separate epitaxy in monolithic stacked and stepped nanosheet field effect transistors (FETs).

Semiconductor devices are used in a variety of electronic applications, such as personal computers, cell phones, digital cameras, and other electronic equipment. Semiconductor devices are usually fabricated by sequentially depositing insulating or dielectric layers, conductive layers, and semiconductive layers of material over a semiconductor substrate, and patterning the various material layers using lithography to form circuit components and elements thereon.

The semiconductor industry has experienced rapid growth due to improvements in the integration density of a variety of electronic components (e.g., transistors, diodes, resistors, capacitors, etc.). For the most part, this improvement in integration density has come from shrinking the semiconductor process node. With the increased demands for miniaturization, higher speed, greater bandwidth, lower power consumption, and lower latency, chip layout has become more complicated and difficult to achieve in the production of semiconductor dies.

### SUMMARY

In accordance with an embodiment, a semiconductor structure is provided. The semiconductor structure includes semiconductor layers of a first nanosheet stack, semiconductor layers of a second nanosheet stack formed over and having a stepped nanosheet formation with respect to the semiconductor layers of the first nanosheet stack, a first epitaxial growth formed adjacent the semiconductor layers of the first nanosheet stack, and a second epitaxial growth formed adjacent the semiconductor layers of the second nanosheet stack such that the second epitaxial growth has a stepped formation with respect to the first epitaxial growth.

In accordance with another embodiment, a semiconductor structure is provided. The semiconductor structure includes a first field effect transistor (FET) stacked over a second FET, where the first FET is disposed in a stepped formation with respect to the second FET, a first epitaxial growth formed adjacent the first FET, and a second epitaxial growth formed adjacent the FET such that the second epitaxial growth occupies a space greater than a space of the first epitaxial growth.

In accordance with yet another embodiment, a method for forming a semiconductor structure is provided. The method includes forming a first nanosheet stack over a second nanosheet stack such that the first nanosheet stack is in a stepped formation with respect to the second nanosheet stack with a sacrificial material disposed adjacent the second nanosheet stack, recessing the second nanosheet stack to form first inner spacers, recessing the first nanosheet stack to form second inner spacers, forming a first epitaxial growth adjacent the first nanosheet stack, depositing an oxide and a nitride cap, and forming a second epitaxial growth adjacent the second nanosheet stack, the second epitaxial growth having a stepped formation with respect to the first epitaxial growth.

It should be noted that the exemplary embodiments are described with reference to different subject-matters. In particular, some embodiments are described with reference to method type claims whereas other embodiments have been described with reference to apparatus type claims. However, a person skilled in the art will gather from the above and the following description that, unless otherwise notified, in addition to any combination of features belonging to one type of subject-matter, also any combination between features relating to different subject-matters, in particular, between features of the method type claims, and features of the apparatus type claims, is considered as to be described within this document.

These and other features and advantages will become apparent from the following detailed description of illustrative embodiments thereof, which is to be read in connection with the accompanying drawings.

### BRIEF DESCRIPTION OF THE DRAWINGS

The invention will provide details in the following description of preferred embodiments with reference to the following figures wherein:

FIG. 1 is a cross-sectional view of a semiconductor structure including a first nanosheet stack and a second nanosheet stack formed over a substrate, where a sacrificial material is formed over the first nanosheet stack and adjacent the second nanosheet stack to create a stepped formation therebetween, in accordance with an embodiment of the present invention;

FIG. 2 is a cross-sectional view of the semiconductor structure of FIG. 1 where a dummy gate and hardmask are deposited over the first and second nanosheet stacks, and patterning takes place, in accordance with an embodiment of the present invention;

FIG. 3 is a cross-sectional view of the semiconductor structure of FIG. 2 where a first spacer is formed adjacent the dummy gate, in accordance with an embodiment of the present invention;

FIG. 4 is a cross-sectional view of the semiconductor structure of FIG. 3 where a recess occurs through the second nanosheet to a top surface of the first nanosheet stack such that the sacrificial material remains intact and the first spacer remains intact, in accordance with an embodiment of the present invention;

FIG. 5 is a cross-sectional view of the semiconductor structure of FIG. 4 where the sacrificial material is selectively etched, in accordance with an embodiment of the present invention;

FIG. 6 is a cross-sectional view of the semiconductor structure of FIG. 5 where a second spacer is formed adjacent the first spacer, adjacent recessed portions of the second nanosheet stack, and adjacent the recessed sacrificial material portions, in accordance with an embodiment of the present invention;

FIG. 7 is a cross-sectional view of the semiconductor structure of FIG. 6 where the first nanosheet stack is selectively recessed, in accordance with an embodiment of the present invention;

FIG. 8 is a cross-sectional view of the semiconductor structure of FIG. 7 where inner spacers are formed in the first nanosheet stack, in accordance with an embodiment of the present invention;

FIG. 9 is a cross-sectional view of the semiconductor structure of FIG. 8 where a bottom epitaxial growth is formed adjacent the inner spacers between the recessed portions of the first nanosheet stack, in accordance with an embodiment of the present invention;

FIG. 10 is a cross-sectional view of the semiconductor structure of FIG. 9 where a dielectric is deposited over the bottom epitaxial growth and a first nitride cap is deposited over the dielectric, in accordance with an embodiment of the present invention;

FIG. 11 is a cross-sectional view of the semiconductor structure of FIG. 10 where the second spacer is removed to expose the first spacer, in accordance with an embodiment of the present invention;

FIG. 12 is a cross-sectional view of the semiconductor structure of FIG. 11 where a top epitaxial growth is formed, in accordance with an embodiment of the present invention;

FIG. 13 is a cross-sectional view of the semiconductor structure of FIG. 12 where a second nitride cap is deposited over the top epitaxial growth, and a patterning stack is deposited, in accordance with an embodiment of the present invention;

FIG. 14 is a cross-sectional view of the semiconductor structure of FIG. 13 where a portion of the top epitaxial growth is selectively etched away, in accordance with an embodiment of the present invention;

FIG. 15 is a cross-sectional view of the semiconductor structure of FIG. 14 where the patterning stack is selectively removed to expose the second nitride cap, in accordance with an embodiment of the present invention; and

FIG. 16 is a cross-sectional view of the semiconductor structure of FIG. 15 where metallization takes place and metal contacts are formed to the top and bottom epitaxial growths, in accordance with an embodiment of the present invention.

Throughout the drawings, same or similar reference numerals represent the same or similar elements.

### DETAILED DESCRIPTION

Embodiments in accordance with the present invention provide methods and devices for constructing a separate epitaxy in monolithic stacked and stepped nanosheet field effect transistors (FETs). In other words, epitaxy is separately grown and isolated. This is achieved by forming the separate N/P epitaxial regions in a stepped nanosheet structure while retaining a ledge to form contacts to the N/P epitaxial regions. Additionally, one of the epitaxy or epitaxial regions has a greater volume (or occupies a greater space) than the other epitaxy or epitaxial region. Further, one epitaxy region is stepped in relation to the other epitaxy region, that is, one epitaxy region has a portion or section that is slightly vertically offset from the other epitaxy region.

Examples of semiconductor materials that can be used in forming such nanosheet structures include silicon (Si), germanium (Ge), silicon germanium alloys (SiGe), silicon carbide (SiC), silicon germanium carbide (SiGeC), III-V compound semiconductors and/or II-VI compound semiconductors. III-V compound semiconductors are materials that include at least one element from Group III of the Periodic Table of Elements and at least one element from Group V of the Periodic Table of Elements. II-VI compound semiconductors are materials that include at least one element from Group II of the Periodic Table of Elements and at least one element from Group VI of the Periodic Table of Elements.

It is to be understood that the present invention will be described in terms of a given illustrative architecture; however, other architectures, structures, substrate materials and process features and steps/blocks can be varied within the scope of the present invention. It should be noted that certain features cannot be shown in all figures for the sake of clarity. This is not intended to be interpreted as a limitation of any particular embodiment, or illustration, or scope of the claims.

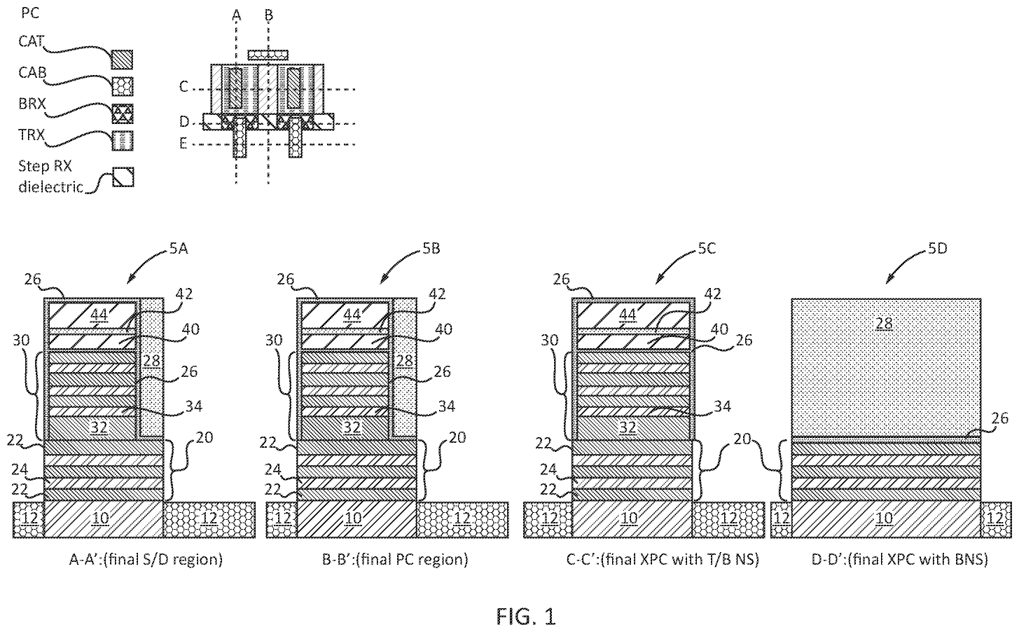

FIG. 1 is a cross-sectional view of a semiconductor structure including a first nanosheet stack and a second nanosheet stack formed over a substrate, where a sacrificial material is formed over the first nanosheet stack and adjacent the second nanosheet stack to create a stepped formation therebetween, in accordance with an embodiment of the present invention.

In various example embodiments, in structure 5A, a first nanosheet stack 20 is formed over a substrate 10. Structure 5A is a cross-sectional view along axis A-A′ (top view) at the source/drain (S/D region). Shallow trench isolation (STI) regions 12 are also present adjacent the substrate 10. A second nanosheet stack 30 is formed over the first nanosheet stack 20. Thus the first and second nanosheet stacks 20, 30 define a stacked configuration. Additionally, the first and second nanosheet stacks 20, 30 define a stepped configuration. The term stepped configuration refers to a stepped structure where one nanosheet is wider than the other nanosheet to create a step or ledge. For example, the first nanosheet stack 20 is wider than the second nanosheet stack 30 such that a stepped region or ledge is formed at the intersection of the first and second nanosheet stacks 20, 30.

The first nanosheet stack 20 includes alternating layers of a first semiconductor material (or layer) 22 and a second semiconductor material (or layer) 24. The first semiconductor material 22 can be, e.g., silicon germanium (SiGe) and the second semiconductor material 24 can be, e.g., silicon (Si).

The second nanosheet stack 30 includes alternating layers of a first semiconductor material (or layer) 32 and a second semiconductor material (or layer) 34. The first semiconductor material 32 can be, e.g., silicon germanium (SiGe) and the second semiconductor material 34 can be, e.g., silicon (Si).

A dielectric liner 26 is formed over the first and second nanosheet stacks 20, 30.

A first oxide layer 40, a nitride layer 42, and a second oxide layer 44 are formed over the second nanosheet stack 30. The dielectric liner 26 is also formed to surround the first oxide layer 40, the nitride layer 42, and the second oxide layer 44. A sacrificial material 28 (or placeholder dielectric) is formed adjacent the second nanosheet stack 30, as well as adjacent to the first oxide layer 40, the nitride layer 42, and the second oxide layer 44. The sacrificial material 28 enables the stepped configuration or formation between the first and second nanosheet stacks 20, 30.

In various example embodiments, structure 5B is a cross-sectional view along axis B-B′(top view) at the PC region. Structure 5B is the same as structure 5A.

In various example embodiments, structure 5C is a cross-sectional view along axis C-C′ (top view) at the XPC with T/B nanosheet. The sacrificial material 28 is not visible in this view.

In various example embodiments, structure 5D is a cross-sectional view along axis D-D′ (top view) at the XPC with BNS. In this view, the second nanosheet stack 30 is not visible. Only the sacrificial material 28 is visible over the first nanosheet stack 20.

In one or more embodiments, the substrate 10 can be a semiconductor or an insulator with an active surface semiconductor layer. The substrate 10 can be crystalline, semi-crystalline, microcrystalline, or amorphous. The substrate 10 can be essentially (e.g., except for contaminants) a single element (e.g., silicon), primarily (e.g., with doping) of a single element, for example, silicon (Si) or germanium (Ge), or the substrate 10 can include a compound, for example, Al₂O₃, SiO₂, GaAs, SiC, or SiGe. The substrate 10 can also have multiple material layers, for example, a semiconductor-on-insulator substrate (SeOI), a silicon-on-insulator substrate (SOI), germanium-on-insulator substrate (GeOI), or silicon-germanium-on-insulator substrate (SGOI). The substrate 10 can also have other layers forming the substrate 10, including high-k oxides and/or nitrides. In one or more embodiments, the substrate 10 can be a silicon wafer. In an embodiment, the substrate 10 is a single crystal silicon wafer.

Referring to, e.g., the first nanosheet stack 20, the first semiconductor material 22 can be the first layer in a stack of sheets of alternating materials. The first nanosheet stack 20 thus includes first semiconductor materials (or layers) 22 and second semiconductor materials (or layers) 24.

Referring to, e.g., the second nanosheet stack 30, the first semiconductor material 32 can be the first layer in a stack of sheets of alternating materials. The second nanosheet stack 30 thus includes first semiconductor materials (or layers) 32 and second semiconductor materials (or layers) 34.

Although it is specifically contemplated that the first semiconductor materials 22/32 can be formed from silicon germanium and that the second semiconductor materials 24/34 can be formed from silicon, it should be understood that any appropriate materials can be used instead, as long as the two semiconductor materials have etch selectivity with respect to one another. As used herein, the term “selective” in reference to a material removal process denotes that the rate of material removal for a first material is greater than the rate of removal for at least another material of the structure to which the material removal process is being applied. The alternating semiconductor materials 22/24 (or 32/34) can be deposited by any appropriate mechanism. It is specifically contemplated that the first and second semiconductor materials 22/24 (or 32/34) can be epitaxially grown from one another, but alternate deposition processes, such as chemical vapor deposition (CVD), physical vapor deposition (PVD), atomic layer deposition (ALD), or gas cluster ion beam (GCIB) deposition, are also contemplated.

In various embodiments, the sacrificial material 28 and the dielectric liner 26 can be a nitride, for example, a silicon nitride (SiN), an oxynitride, for example, silicon oxynitride (SiON), or a combination thereof. In one example, the sacrificial material 28 can be amorphous silicon germanium (a-SiGe).

In various embodiments, the first oxide layer 40 and the second oxide layer 44 can be, e.g., silicon oxide (SiO₂).

In various embodiments, the nitride layer 42 can be, e.g., silicon nitride (SiN).

Regarding various dielectrics or dielectric layers discussed herein, the dielectrics can include, but are not limited to, SiN, SiOCN, SiOC, SiBCN, SiO₂, SO₂, or ultra-low-k (ULK) materials, such as, for example, porous silicates, carbon doped oxides, silicon dioxides, silicon nitrides, silicon oxynitrides, carbon-doped silicon oxide (SiCOH) and porous variants thereof, silsesquioxanes, siloxanes, or other dielectric materials having, for example, a dielectric constant in the range of about 2 to about 10.

In some embodiments, the dielectrics can be conformally deposited using atomic layer deposition (ALD) or, chemical vapor deposition (CVD). Variations of CVD processes suitable for forming the dielectrics include, but are not limited to, Atmospheric Pressure CVD (APCVD), Low Pressure CVD (LPCVD) and Plasma Enhanced CVD (PECVD), Metal-Organic CVD (MOCVD) and combinations thereof can also be employed.

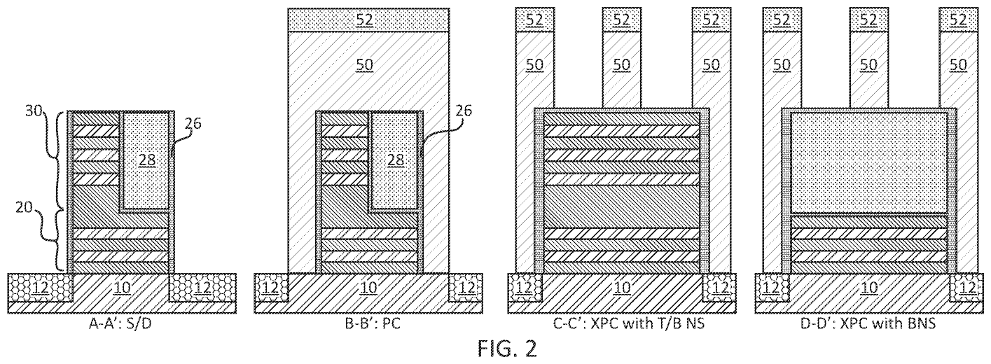

FIG. 2 is a cross-sectional view of the semiconductor structure of FIG. 1 where a dummy gate and hardmask are deposited over the first and second nanosheet stacks, and patterning takes place, in accordance with an embodiment of the present invention.

In various example embodiments, a dummy gate 50 and a hardmask 52 are deposited over the first and second nanosheet stacks 20, 30, and patterning takes place. The patterning results in the selective removal of the first oxide layer 40, the nitride layer 42, and the second oxide layer 44.

In structure 5A, the dummy gate 50 and the hardmask 52 are not visible.

In structure 5B, the dummy gate 50 and the hardmask 52 completely surround the first and second nanosheet stacks 20, 30.

In structures 5C and 5D, the dummy gate 50 and the hardmask 52 are visible as they form fin-shaped structures or columns or pillars.

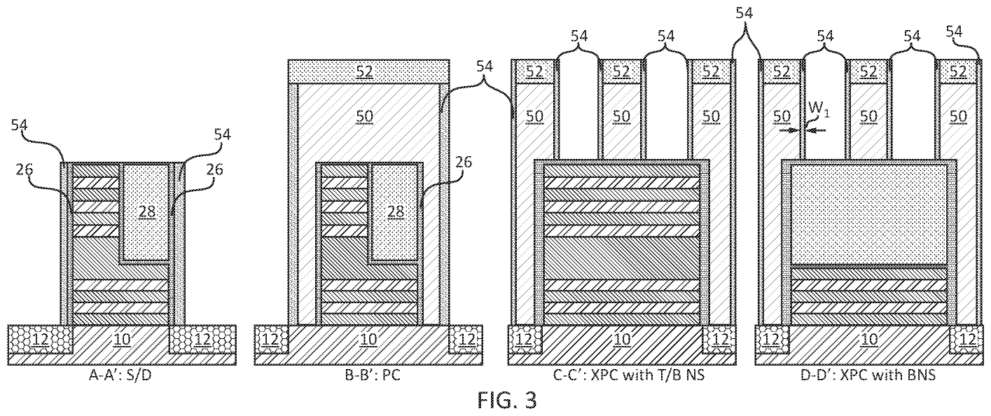

FIG. 3 is a cross-sectional view of the semiconductor structure of FIG. 2 where a first spacer is formed adjacent the dummy gate, in accordance with an embodiment of the present invention.

In various example embodiments, a first spacer 54 is formed adjacent the dummy gate 50, as well as the hardmask 52. The first spacer 54 can have a width “W1.”

The first spacer 54 can include any of one or more of SiN, SiBN, SiCN and/or SiBCN films.

In structure 5A, the first spacer 54 directly contacts the sidewall of the dielectric liner 26.

In structure 5B, the first spacer 54 directly contacts the sidewall of the dummy gate 50.

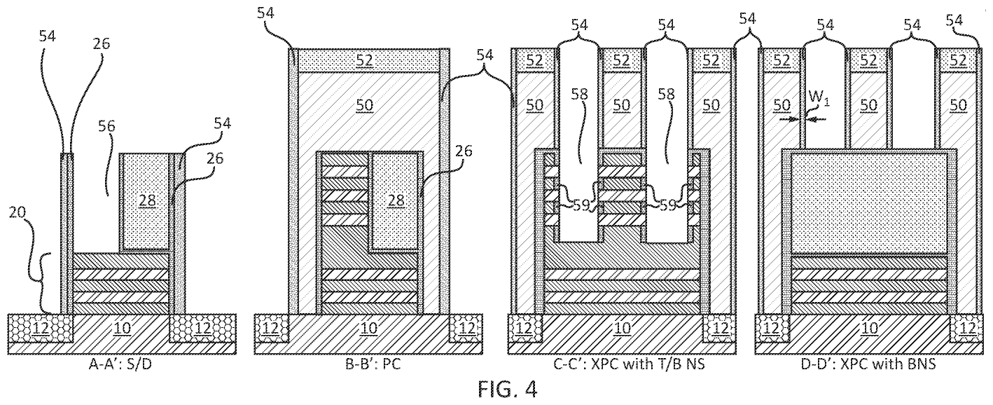

FIG. 4 is a cross-sectional view of the semiconductor structure of FIG. 3 where a recess occurs through the second nanosheet to a top surface of the first nanosheet stack such that the sacrificial material remains intact and the first spacer remains intact, in accordance with an embodiment of the present invention.

In various example embodiments, in structure 5A, a recess 56 occurs through the second nanosheet stack 30 to a top surface of the first nanosheet stack 20 such that the sacrificial material 28 remains intact and the first spacer 54 remains intact.

In structure 5C, a recess 58 occurs through the second nanosheet stack 30 to a top surface of the first nanosheet stack 20, and inner spacers 59 are formed. This step can be referred to as a top S/D recess selective to a placeholder dielectric (e.g., the sacrificial material 28). The sacrificial material 28 prevents the bottom sheet from recessing in the step region.

The inner spacers 59 can include any of one or more of SiN, SiBN, SiCN and/or SiBCN films.

The etching can include a dry etching process such as, for example, reactive ion etching, plasma etching, ion etching or laser ablation. The etching can further include a wet chemical etching process in which one or more chemical etchants are used to remove portions of the blanket layers that are not protected by the patterned photoresist.

The dry and wet etching processes can have etching parameters that can be tuned, such as etchants used, etching temperature, etching solution concentration, etching pressure, source power, RF bias voltage, RF bias power, etchant flow rate, and other suitable parameters. Dry etching processes can include a biased plasma etching process that uses a chlorine-based chemistry. Other dry etchant gasses can include Tetrafluoromethane (CF₄), nitrogen trifluoride (NF₃), sulfur hexafluoride (SF₆), and helium (He), and Chlorine trifluoride (ClF₃). Dry etching can also be performed anisotropically using such mechanisms as DRIE (deep reactive-ion etching). Chemical vapor etching can be used as a selective etching method, and the etching gas can include hydrogen chloride (HCl), Tetrafluoromethane (CF₄), and gas mixture with hydrogen (H₂). Chemical vapor etching can be performed by CVD with suitable pressure and temperature.

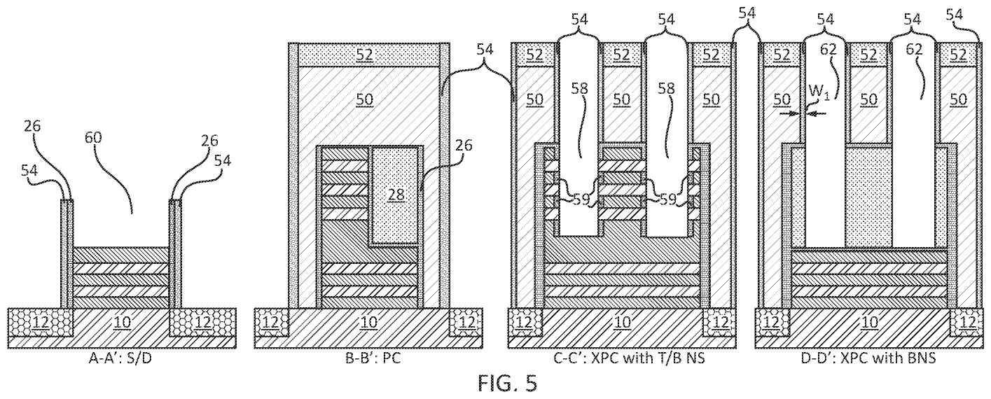

FIG. 5 is a cross-sectional view of the semiconductor structure of FIG. 4 where the sacrificial material is selectively etched, in accordance with an embodiment of the present invention.

In various example embodiments, the sacrificial material 28 is selectively etched.

In structure 5A, the sacrificial material 28 is completely removed to create opening 60 and to expose a top surface of the first nanosheet stack 20.

In structure 5D, openings 62 are created to a top surface of the first nanosheet stack 20.

Structures 5B and 5C remain the same.

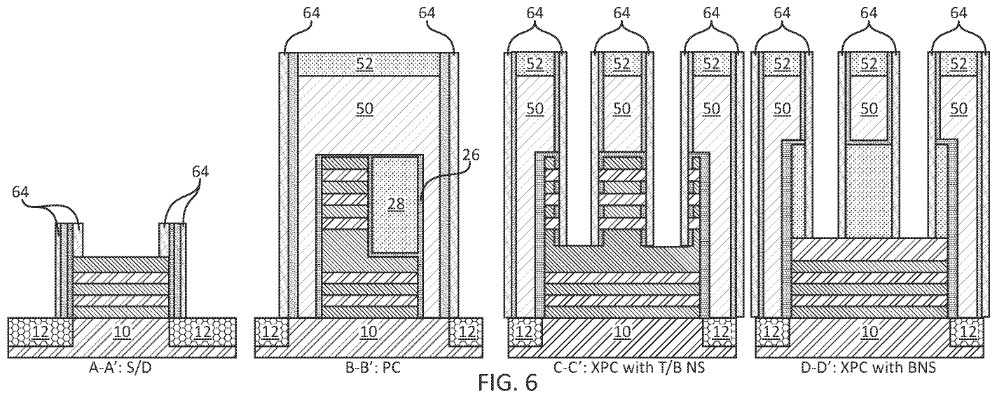

FIG. 6 is a cross-sectional view of the semiconductor structure of FIG. 5 where a second spacer is formed adjacent the first spacer, adjacent recessed portions of the second nanosheet stack, and adjacent the recessed sacrificial material portions, in accordance with an embodiment of the present invention.

In various example embodiments, a second spacer 64 is formed adjacent the first spacer 54, adjacent recessed portions of the second nanosheet stack 30, and adjacent the recessed sacrificial material portions.

The second spacer 64 can include any of one or more of SiN, SiBN, SiCN and/or SiBCN films.

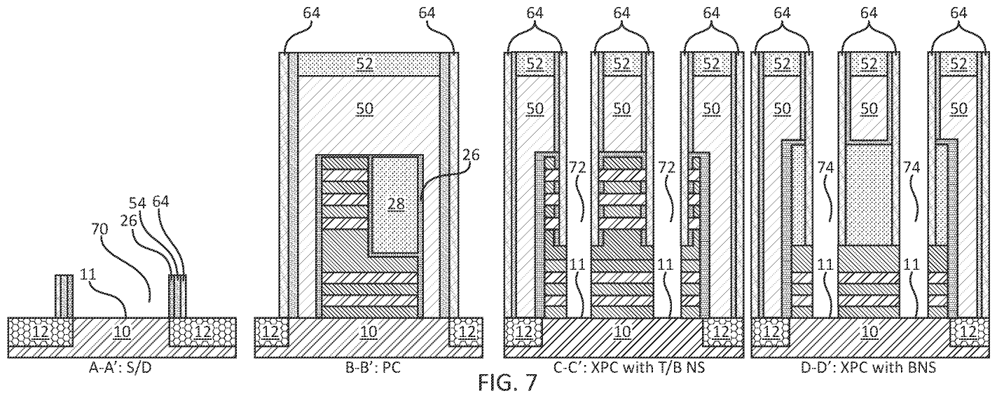

FIG. 7 is a cross-sectional view of the semiconductor structure of FIG. 6 where the first nanosheet stack is selectively recessed, in accordance with an embodiment of the present invention.

In various example embodiments, the first nanosheet stack 20 is selectively recessed. This can be referred to as a bottom S/D recess.

In structure 5A, the first nanosheet stack 20 is completely removed. An opening 70 is created to a top surface 11 of the substrate 10. The dielectric liner 26, the first spacer 54, and the second spacer 64 remain intact.

In structure 5C, openings 72 are created within the first nanosheet stack 20 to the top surface 11 of the substrate 10.

In structure 5D, openings 74 are created within the first nanosheet stack 20 to the top surface 11 of the substrate 10.

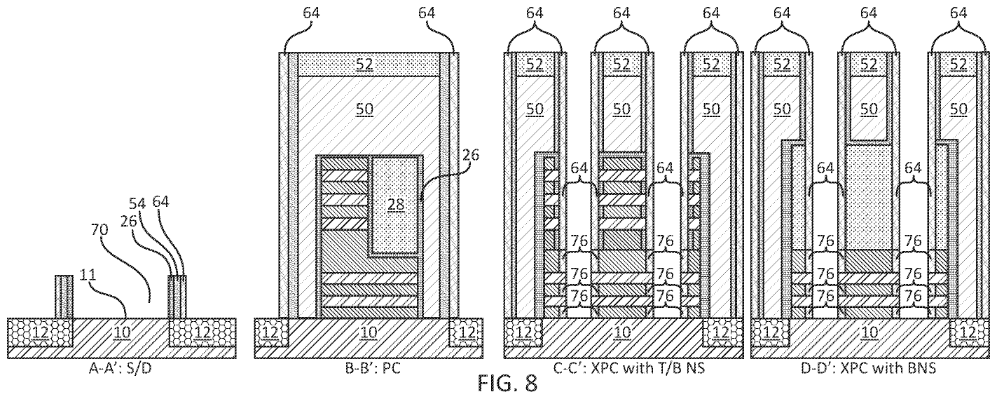

FIG. 8 is a cross-sectional view of the semiconductor structure of FIG. 7 where inner spacers are formed in the first nanosheet stack, in accordance with an embodiment of the present invention.

In various example embodiments, inner spacers 76 are formed in the first nanosheet stack 20.

The inner spacers 76 can include any of one or more of SiN, SiBN, SiCN and/or SiBCN films.

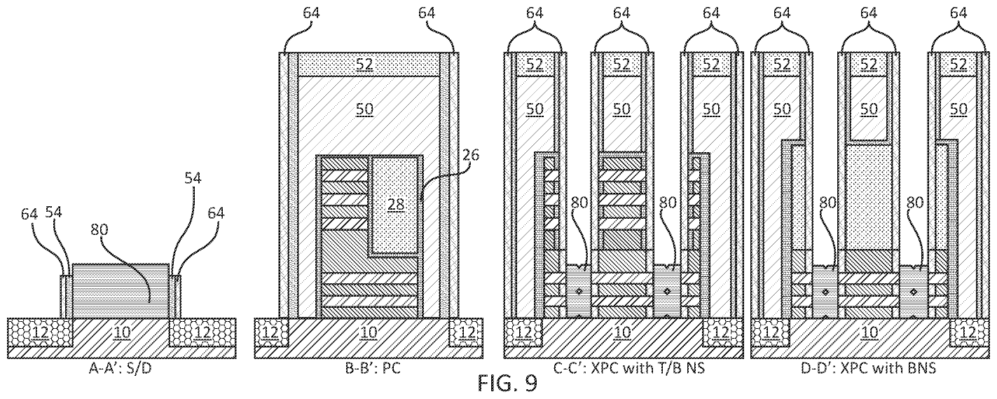

FIG. 9 is a cross-sectional view of the semiconductor structure of FIG. 8 where a bottom epitaxial growth is formed adjacent the inner spacers between the recessed portions of the first nanosheet stack, in accordance with an embodiment of the present invention.

In various example embodiments, a bottom epitaxial growth 80 is formed adjacent the inner spacers 76 between the recessed portions of the first nanosheet stack 20 (structures 5C and 5D). The bottom epitaxial growth 80 can also be referred to as a bottom epitaxy region.

The bottom epitaxial growth 80 can be of the same or different materials for pFET and nFET devices, and can be either in-situ doped with appropriate polarity dopants (B for pFET and P for nFET devices) or doped by ion implantation.

The terms “epitaxial growth” and “epitaxial deposition” refer to the growth of a semiconductor material on a deposition surface of a semiconductor material, in which the semiconductor material being grown has substantially the same crystalline characteristics as the semiconductor material of the deposition surface. The term “epitaxial material” denotes a material that is formed using epitaxial growth. In some embodiments, when the chemical reactants are controlled and the system parameters set correctly, the depositing atoms arrive at the deposition surface with sufficient energy to move around on the surface and orient themselves to the crystal arrangement of the atoms of the deposition surface. Thus, in some examples, an epitaxial film deposited on a {100} crystal surface will take on a {100} orientation.

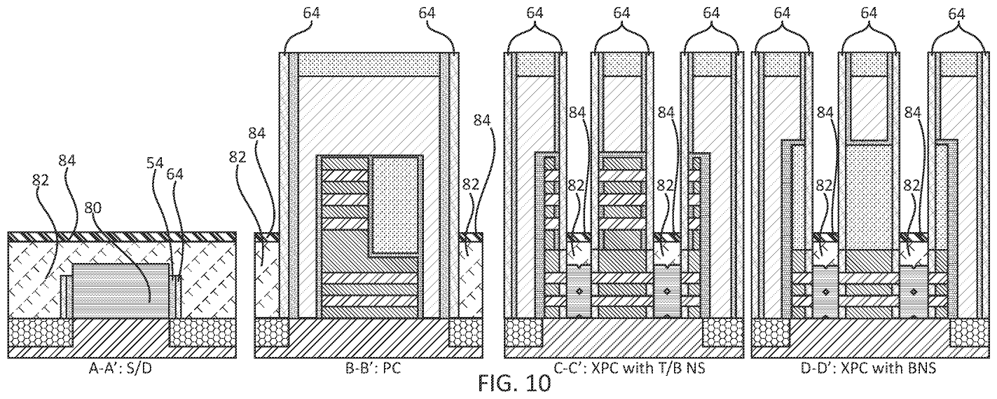

FIG. 10 is a cross-sectional view of the semiconductor structure of FIG. 9 where a dielectric is deposited over the bottom epitaxial growth and a first nitride cap is deposited over the dielectric, in accordance with an embodiment of the present invention.

In various example embodiments, a dielectric 82 is deposited over the bottom epitaxial growth 80 and a first nitride cap 84 is deposited over the dielectric 82. The dielectric 82 can be an oxide, whereas the first nitride cap 84 can include SiN.

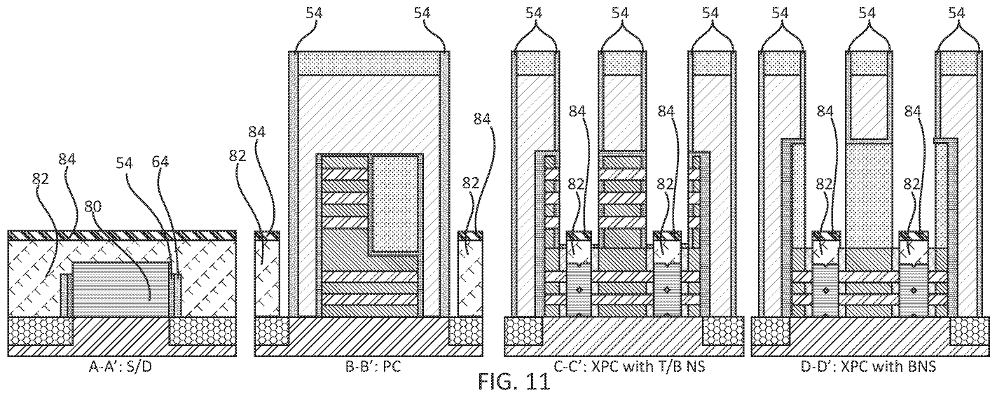

FIG. 11 is a cross-sectional view of the semiconductor structure of FIG. 10 where the second spacer is removed to expose the first spacer, in accordance with an embodiment of the present invention.

In various example embodiments, the second spacer 64 is removed to expose the first spacer 54.

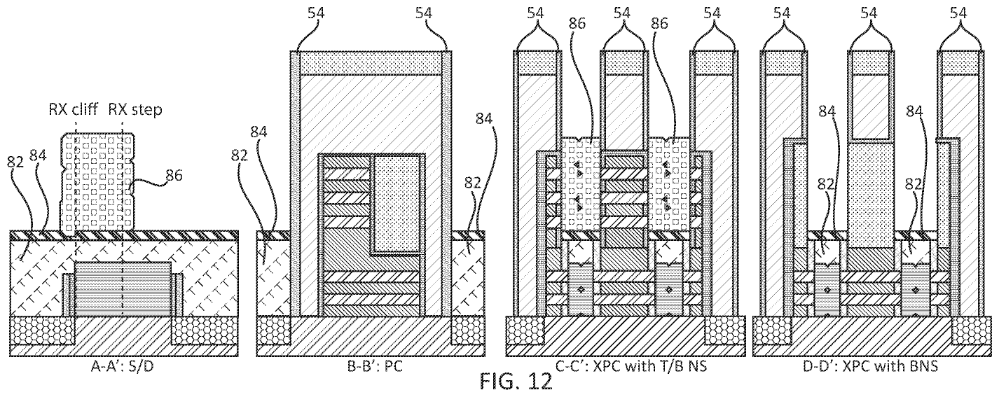

FIG. 12 is a cross-sectional view of the semiconductor structure of FIG. 11 where a top epitaxial growth is formed, in accordance with an embodiment of the present invention.

In various example embodiments, a top epitaxial growth 86 is formed over the first nitride cap 84. The top epitaxial growth 86 occupies a greater space than the bottom epitaxial growth 80. In other words, the top epitaxial growth 86 has a larger volume than the bottom epitaxial growth 80. The top epitaxial growth 86 can also be referred to as a top epitaxy region.

The top epitaxial growth 86 can be of the same or different materials for pFET and nFET devices, and can be either in-situ doped with appropriate polarity dopants (B for pFET and P for nFET devices) or doped by ion implantation.

The top epitaxial growth 86 is visible in structures 5A and 5C. The top epitaxial growth 86 is vertically aligned with the bottom epitaxial growth 80.

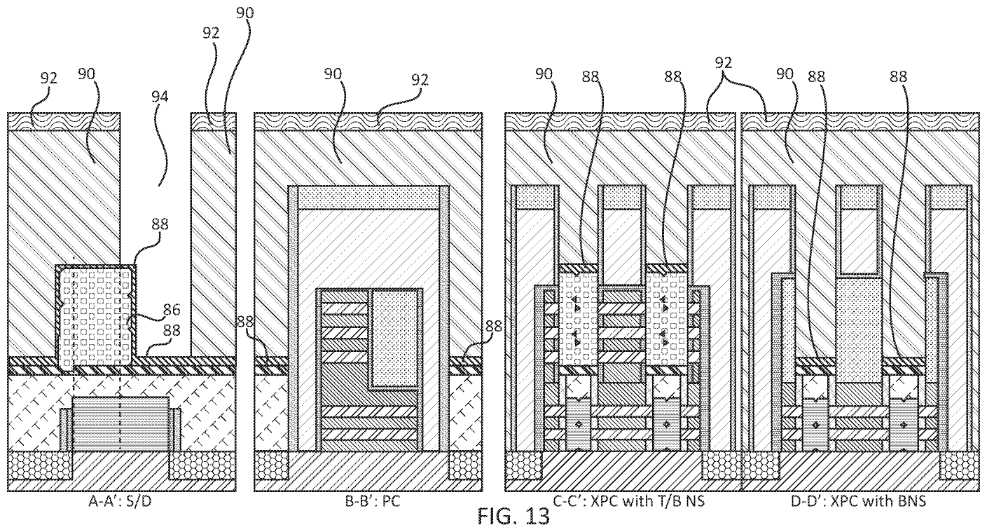

FIG. 13 is a cross-sectional view of the semiconductor structure of FIG. 12 where a second nitride cap is deposited over the top epitaxial growth, and a patterning stack is deposited, in accordance with an embodiment of the present invention.

In various example embodiments, a second nitride cap 88 is deposited over the top epitaxial growth 86, and a patterning stack is deposited. The patterning stack includes a first layer 90 and a second layer 92. The first layer 90 can be a dielectric material and the second layer 92 can be a hardmask. An opening 94 is created in structure 5A to expose a portion of the second nitride cap 88, as well as a portion of the top epitaxial growth 86.

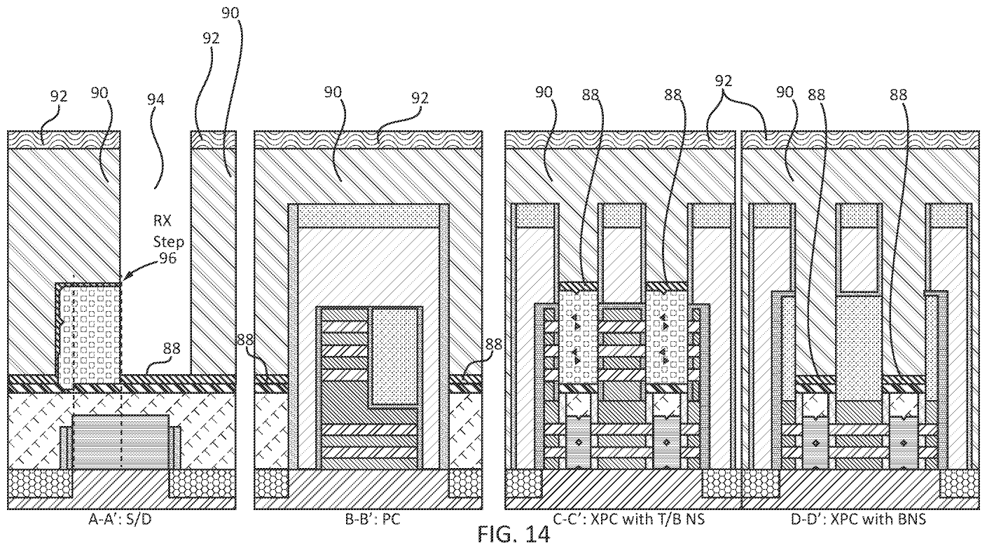

FIG. 14 is a cross-sectional view of the semiconductor structure of FIG. 13 where a portion of the top epitaxial growth is selectively etched away, in accordance with an embodiment of the present invention.

In various example embodiments, the exposed portion of the top epitaxial growth 86 and the exposed portion of the second nitride cap 88 are selectively etched away. Such portions can be selectively etched by, e.g., a reactive ion etch (RIE). Therefore, the sacrificial material 28 aids in the RX step formation 96 and top only S/D recess. The sharp top epi edge is formed by the cut mask in structure 5A. Also, the multi-layer spacer blocks the top epi while the bottom epi is grown. Finally, the bottom spacer and oxide fill enables isolation between the N/P epi regions.

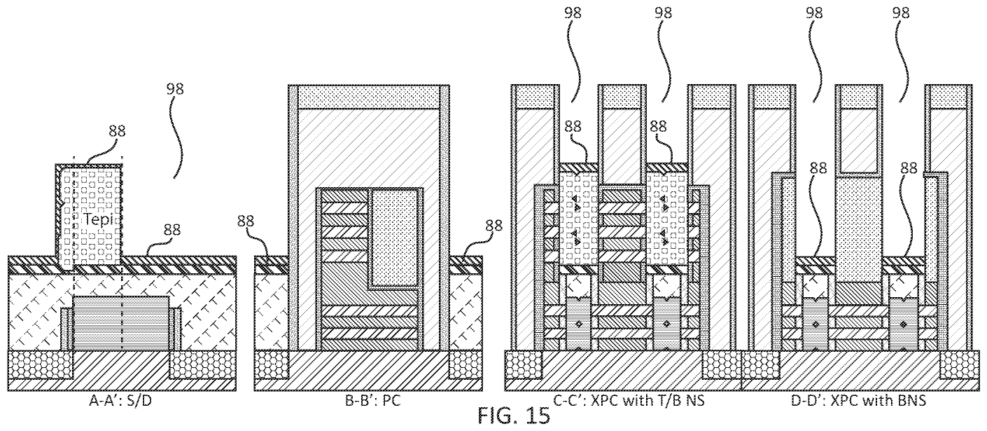

FIG. 15 is a cross-sectional view of the semiconductor structure of FIG. 14 where the patterning stack is selectively removed to expose the second nitride cap, in accordance with an embodiment of the present invention.

In various example embodiments, the patterning stack with the first layer 90 and the second layer 92 are selectively removed to expose the second nitride cap 88. Openings 98 are created to a top surface of the second nitride cap 88 in structures 5C and 5D.

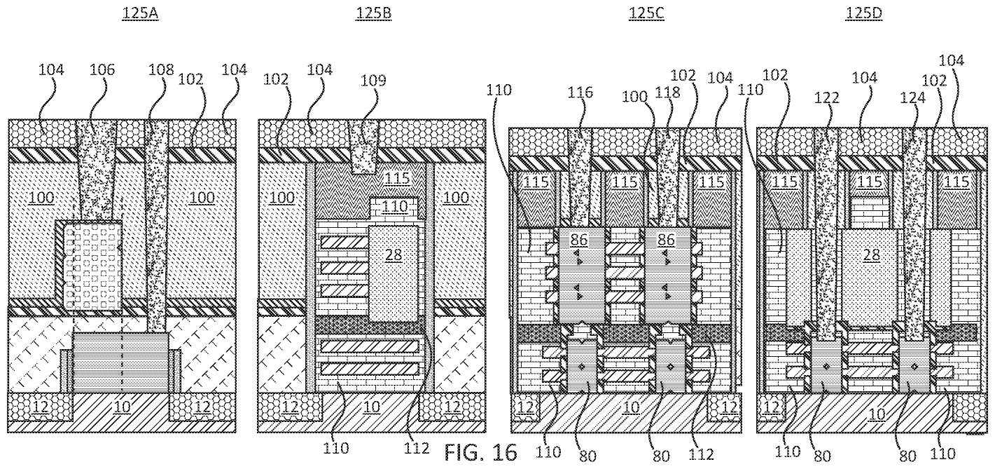

FIG. 16 is a cross-sectional view of the semiconductor structure of FIG. 15 where metallization takes place and metal contacts are formed to the top and bottom epitaxial growths, in accordance with an embodiment of the present invention.

In various example embodiments, metallization takes place and metal contacts are formed to the top and bottom epitaxial growths.

In particular, in structure 125A (along axis A-A′; top view of FIG. 1), a first oxide material 100 is deposited and a third nitride cap 102 is deposited over the first oxide layer 100. A second oxide material 104 is then formed over the third nitride cap 102. A first metal contact 106 is formed to a top surface of the top epitaxial growth 86 and a second metal contact 108 is formed to a top surface of the bottom epitaxial growth 80. Thus, a stepped nanosheet structure is shown with a dielectric block to aid in epitaxial separation. A multilayer spacer was employed to grow the epitaxial regions separately. An oxide fill with a bottom nitride spacer was employed to isolate the N epitaxial regions from the P epitaxial regions.

In structure 125B, (along axis B-B′; top view of FIG. 1), the sacrificial semiconductor layers (SiGe layers of the first nanosheet stack 20) and the sacrificial semiconductor layers (SiGe layers of the second nanosheet stack 30) are selectively removed and replaced with a first replacement metal gate (RMG) 110. The first RMG 110 of the first nanosheet stack 20 is separated from the first RMG 110 of the second nanosheet stack 30 by a dielectric layer 112. A second RMG 115 is formed over the first RMG 110 of the second nanosheet stack 30. A third metal contact 109 extends to the second RMG 115. The sacrificial material 28 extends into the dielectric layer 112.

In structure 125C, (along axis C-C′; top view of FIG. 1), the sacrificial semiconductor layers (SiGe layers of the first nanosheet stack 20) and the sacrificial semiconductor layers (SiGe layers of the second nanosheet stack 30) are selectively removed and replaced with the first RMG 110. The second RMG 115 extends to a top surface of the first RMG 110 of the second semiconductor stack 30. The contacts 116, 118 extend to a top surface of the top epitaxial growth 86. Therefore, the bottom epitaxial growth 80 has been separately grown and isolated from the top epitaxial growth 86. Also, the top epitaxial growth 86 has a greater volume than the bottom epitaxial growth 80.

In structure 125D, (along axis D-D′; top view of FIG. 1), the sacrificial semiconductor layers (SiGe layers of the first nanosheet stack 20) and the sacrificial semiconductor layers (SiGe layers of the second nanosheet stack 30) are selectively removed and replaced with the first RMG 110. The second RMG 115 extends to a top surface of the first RMG 110 of the second semiconductor stack 30. The contacts 122, 124 extend to a top surface of the bottom epitaxial growth 80.

Therefore, structures 125A-125D illustrate semiconductor layers of a first nanosheet stack, semiconductor layers of a second nanosheet stack formed over and having a stepped nanosheet formation with respect to the semiconductor layers of the first nanosheet stack, a first epitaxial growth formed adjacent the semiconductor layers of the first nanosheet stack, and a second epitaxial growth formed adjacent the semiconductor layers of the second nanosheet stack such that the second epitaxial growth has a stepped formation with respect to the first epitaxial growth. The second epitaxial growth has a volume greater than a volume of the first epitaxial growth. The first epitaxial growth is isolated from the second epitaxial growth by an oxide layer and a nitride cap. A first work function metal (WFM) surrounds the semiconductor layers of the first nanosheet stack and the semiconductor layers of the second nanosheet stack. A second WFM is placed over and in direct contact with the first WFM. The first WFM is horizontally aligned with the first and second epitaxial growths. Inner spacers are disposed directly between the first WFM and the first epitaxial growth. Inner spacers are further disposed directly between the first WFM and the second epitaxial growth. Also, inner spacers of the first epitaxial growth are vertically offset from inner spacers of the second epitaxial growth.

Stated differently, structures 125A-125D illustrate a first field effect transistor (FET) stacked over a second FET, where the first FET is disposed in a stepped formation with respect to the second FET, a first epitaxial growth formed adjacent the first FET, and a second epitaxial growth formed adjacent the FET such that the second epitaxial growth occupies a space greater than a space of the first epitaxial growth. The second epitaxial growth has a stepped formation with respect to the first epitaxial growth. The first epitaxial growth is isolated from the second epitaxial growth by an oxide layer and a nitride cap. A first work function metal (WFM) surrounds semiconductor layers of the first and second FETs. A second WFM is placed over and in direct contact with the first WFM. The first WFM is horizontally aligned with the first and second epitaxial growths. Further, inner spacers are disposed directly between the first WFM and the first epitaxial growth, and between the first WFM and the second epitaxial growth.

The high-k metal gate material of the first and second RMGs 110, 115 can be deposited by any suitable techniques, such as ALD, CVD, metal-organic CVD (MOCVD), physical vapor deposition (PVD), thermal oxidation, combinations thereof, or other suitable techniques. The first and second RMGs 110, 115 can include a gate dielectric layer, e.g., HfO₂, LaO, AlO, ZrO, TiO, Ta₂O₅, Y₂O₃, SrTiO₃(STO), BaTiO₃ (BTO), BaZrO, HfZrO, HfLaO, HfSiO, LaSiO, AlSiO, HfTaO, HfTiO, (Ba,Sr)TiO₃ (BST), Al₂O₃, Si₃N₄, oxynitrides (SiON), or other suitable materials. The first and second RMGs 110, 115 further include work function metals (WFMs), such as TIN, TIC, TiAl, TiAlC, etc., and conductive metal fills such as W, Al, or Ru.

Non-limiting examples of suitable conductive materials for the first metal contact 106 and the second metal contact 108 (as well as the third metal contact 109 and contacts 116/118, 122/124) include a silicide liner such as Ti, Ni, NiPt, etc., an adhesion metal liner, such as TiN, TaN, and conductive metal fill, such as Al, W, Co, Ru, etc. The conductive material can further include dopants that are incorporated during or after deposition. The conductive metal can be deposited by a suitable deposition process, for example, CVD, PECVD, PVD, plating, thermal or e-beam evaporation, and sputtering.

In conclusion, the exemplary embodiments of the present invention present methods and devices for constructing a separate epitaxy in monolithic stacked and stepped nanosheet FETs. In other words, epitaxy is separately grown and isolated. This is achieved by forming the separate N/P epitaxial regions in a stepped nanosheet structure while retaining a ledge to form contacts to the N/P epitaxial regions. Additionally, one of the epitaxy or epitaxial regions has a greater volume (or occupies a greater space) than the other epitaxy or epitaxial region. Further, one epitaxy region is stepped in relation to the other epitaxy region, that is, one epitaxy region has a portion or section that is slightly vertically offset from the other epitaxy region. Thus, formation of separate N/P epitaxial regions in a stepped structure is achieved.

Moreover, the exemplary method includes forming a first nanosheet stack over a second nanosheet stack such that the first nanosheet stack is in a stepped formation with respect to the second nanosheet stack with a sacrificial material disposed adjacent the second nanosheet stack, recessing the second nanosheet stack to form first inner spacers, recessing the first nanosheet stack to form second inner spacers, forming a first epitaxial growth adjacent the first nanosheet stack, depositing an oxide and a nitride cap, and forming a second epitaxial growth adjacent the second nanosheet stack, the second epitaxial growth having a stepped formation with respect to the first epitaxial growth. The second epitaxial growth has a volume greater than a volume of the first epitaxial growth. The second inner spacers are vertically offset from the first inner spacers.

Regarding FIGS. 1-16, deposition is any process that grows, coats, or otherwise transfers a material onto the wafer. Available technologies include, but are not limited to, thermal oxidation, physical vapor deposition (PVD), chemical vapor deposition (CVD), electrochemical deposition (ECD), molecular beam epitaxy (MBE) and more recently, atomic layer deposition (ALD) among others. As used herein, “depositing” can include any now known or later developed techniques appropriate for the material to be deposited including but not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metal-organic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

The term “processing” as used herein includes deposition of material or photoresist, patterning, exposure, development, etching, cleaning, stripping, implanting, doping, stressing, layering, and/or removal of the material or photoresist as needed in forming a described structure.

Removal is any process that removes material from the wafer: examples include etch processes (either wet or dry), and chemical-mechanical planarization (CMP), etc.

Patterning is the shaping or altering of deposited materials, and is generally referred to as lithography. For example, in conventional lithography, the wafer is coated with a chemical called a photoresist; then, a machine called a stepper focuses, aligns, and moves a mask, exposing select portions of the wafer below to short wavelength light; the exposed regions are washed away by a developer solution. After etching or other processing, the remaining photoresist is removed. Patterning also includes electron-beam lithography.

It is to be understood that the present invention will be described in terms of a given illustrative architecture; however, other architectures, structures, substrate materials and process features and steps/blocks can be varied within the scope of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical mechanisms (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which usually include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present embodiments. The compounds with additional elements will be referred to herein as alloys.

Reference in the specification to “one embodiment” or “an embodiment” of the present invention, as well as other variations thereof, means that a particular feature, structure, characteristic, and so forth described in connection with the embodiment is included in at least one embodiment of the present invention. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of methods and structures providing for constructing a separate epitaxy in monolithic stacked and stepped nanosheet field effect transistors (FETs) (which are intended to be illustrative and not limiting), it is noted that modifications and variations can be made by persons skilled in the art in light of the above teachings. It is therefore to be understood that changes may be made in the particular embodiments described which are within the scope of the invention as outlined by the appended claims. Having thus described aspects of the invention, with the details and particularity required by the patent laws, what is claimed and desired protected by Letters Patent is set forth in the appended claims.

1. A semiconductor structure comprising:
semiconductor layers of a first nanosheet stack;
semiconductor layers of a second nanosheet stack formed over and having a stepped nanosheet formation with respect to the semiconductor layers of the first nanosheet stack;
a first epitaxial growth formed adjacent the semiconductor layers of the first nanosheet stack; and
a second epitaxial growth formed adjacent the semiconductor layers of the second nanosheet stack such that the second epitaxial growth has a stepped formation with respect to the first epitaxial growth.

2. The semiconductor structure of claim 1, wherein the second epitaxial growth has a volume greater than a volume of the first epitaxial growth.

3. The semiconductor structure of claim 1, wherein the first epitaxial growth is isolated from the second epitaxial growth by an oxide layer and a nitride cap.

4. The semiconductor structure of claim 1, wherein a first work function metal (WFM) surrounds the semiconductor layers of the first nanosheet stack and the semiconductor layers of the second nanosheet stack.

5. The semiconductor structure of claim 4, wherein a second WFM is placed over and in direct contact with the first WFM.

6. The semiconductor structure of claim 4, wherein the first WFM is horizontally aligned with the first and second epitaxial growths.

7. The semiconductor structure of claim 4, wherein inner spacers are disposed directly between the first WFM and the first epitaxial growth.

8. The semiconductor structure of claim 4, wherein inner spacers are disposed directly between the first WFM and the second epitaxial growth.

9. The semiconductor structure of claim 1, wherein inner spacers of the first epitaxial growth are vertically offset from inner spacers of the second epitaxial growth.

10. A semiconductor structure comprising:
a first field effect transistor (FET) stacked over a second FET, where the first FET is disposed in a stepped formation with respect to the second FET;
a first epitaxial growth formed adjacent the first FET; and
a second epitaxial growth formed adjacent the FET such that the second epitaxial growth occupies a space greater than a space of the first epitaxial growth.

11. The semiconductor structure of claim 10, wherein the second epitaxial growth has a stepped formation with respect to the first epitaxial growth.

12. The semiconductor structure of claim 10, wherein the first epitaxial growth is isolated from the second epitaxial growth by an oxide layer and a nitride cap.

13. The semiconductor structure of claim 10, wherein a first work function metal (WFM) surrounds semiconductor layers of the first and second FETs.

14. The semiconductor structure of claim 13, wherein a second WFM is placed over and in direct contact with the first WFM.

15. The semiconductor structure of claim 13, wherein the first WFM is horizontally aligned with the first and second epitaxial growths.

16. The semiconductor structure of claim 13, wherein inner spacers are disposed directly between the first WFM and the first epitaxial growth, and between the first WFM and the second epitaxial growth.

17. The semiconductor structure of claim 10, wherein inner spacers of the first epitaxial growth are vertically offset from inner spacers of the second epitaxial growth.

18. A method comprising:
forming a first nanosheet stack over a second nanosheet stack such that the first nanosheet stack is in a stepped formation with respect to the second nanosheet stack with a sacrificial material disposed adjacent the second nanosheet stack;
recessing the second nanosheet stack to form first inner spacers;
recessing the first nanosheet stack to form second inner spacers;
forming a first epitaxial growth adjacent the first nanosheet stack;
depositing an oxide and a nitride cap; and
forming a second epitaxial growth adjacent the second nanosheet stack, the second epitaxial growth having a stepped formation with respect to the first epitaxial growth.

19. The method of claim 18, wherein the second inner spacers are vertically offset from the first inner spacers.

20. The method of claim 18, wherein the second epitaxial growth has a volume greater than a volume of the first epitaxial growth.
